(19) United States
(12) Patent Application Publication
(10) Pub. No.: US 2025/0220817 A1
(43) Pub. Date: Jul. 3, 2025

(54) MULTIPHASE TRANSINDUCTORS FOR ADVANCED VERTICAL POWER DELIVERY MODULES

(71) Applicant: AcLeap Power Inc., Taipei City (TW)

(72) Inventor: Arturo Silva, Allen, TX (US)

(21) Appl. No.: 18/916,928

(22) Filed: Oct. 16, 2024

Related U.S. Application Data
(60) Provisional application No. 63/615,552, filed on Dec. 28, 2023.

(51) Int. Cl. H05K 1/14; H01F 27/26; H01F 27/29; H01F 27/30; H05K 1/18

(52) U.S. Cl. CPC H05K 1/145; H01F 27/266; H01F 27/292; H01F 27/306; H05K 1/181; H01F 2027/297; H05K 2201/1003; H05K 2201/10265

(57) ABSTRACT

In one embodiment, a power delivery module is provided. The power delivery module includes a first printed circuit board (PCB), a second PCB, a transinductor core, and at least one electrically conductive pillar. The transinductor core is sandwiched between the first PCB and the second PCB, and the transinductor core includes at least one slot exposing the first PCB to the second PCB. The at least one electrically conductive pillar extends through the at least one slot and electrically connects the first PCB to the second PCB.

### CROSS-REFERENCE TO RELATED APPLICATIONS

This application claims priority to U.S. Provisional Patent Application No. 63/615,552, filed Dec. 28, 2023 and titled “MULTIPHASE TRANSINDUCTORS FOR ADVANCED VERTICAL POWER DELIVERY MODULES”, the entire contents of which are hereby incorporated by reference.

### BACKGROUND

The field of the disclosure relates to power delivery modules, and in particular, to power delivery modules that utilize multiphase transinductors.

Typical power delivery modules face significant challenges in optimizing performance, particularly in high-performance computing systems. The placement of power delivery components, such as inductors, is crucial when supporting high-current application specific integrated circuits (ASICs), point of load power delivery for servers, telecommunication applications, etc. Traditional approaches often fail to efficiently address the spatial and thermal constraints associated with these types of applications. Therefore, achieving optimal power delivery while minimizing the height of the power delivery module is desirable to ensure the reliability and efficiency of the power delivery module in addition to improving the power density of the power delivery module.

### BRIEF DESCRIPTION

In one embodiment, a power delivery module is provided. The power delivery module includes a first printed circuit board (PCB), a second PCB, a transinductor core, and at least one electrically conductive pillar. The transinductor core is sandwiched between the first PCB and the second PCB, and the transinductor core includes at least one slot exposing the first PCB to the second PCB. The at least one electrically conductive pillar extends through the at least one slot and electrically connects the first PCB to the second PCB.

In another embodiment, a winding assembly is provided. The winding assembly includes a first PCB, a second PCB, at least one transinductor core sandwiched between the first PCB and the second PCB, and pairs of electrically conductive pillars. Each transinductor core includes a first side portion, a second side portion, and a central portion. The central portion is sandwiched between the first side portion and the second side portion. The central portion includes a plurality of crossbars that extend towards the first side portion and the second side portion, and the plurality of crossbars define a plurality of slots. The pairs of electrically conductive pillars extend through the plurality of slots and electrically connect the first PCB to the second PCB. Each of the pairs of electrically conductive pillars form primary and secondary windings for the at least one transinductor core.

In another embodiment, a power delivery module is provided. The power delivery module includes a first PCB, a second PCB, a transinductor core sandwiched between the first PCB and the second PCB, pairs of electrically conductive pillars, a plurality of interconnect pillars, a plurality of conductive traces, and a controller. The transinductor core includes a first side portion, a second side portion, and a central portion. The central portion is sandwiched between the first side portion and the second side portion. The central portion includes a plurality of crossbars that extend towards the first side portion and the second side portion, and the plurality of crossbars define a plurality of slots. The pairs of electrically conductive pillars extend through the plurality of slots and electrically connect the first PCB to the second PCB. Each of the pairs of electrically conductive pillars form primary and secondary windings for the transinductor core. The plurality of interconnect pillars are external to the transinductor core and extend between the first PCB and the second PCB. The plurality of conductive traces are formed at the first PCB and the second PCB and electrically connect, via the plurality of interconnect pillars, the pairs of electrically conductive pillars in a winding arrangement. The controller is configured to perform pulse width modulation phase sequencing of the primary winding associated with each of the pairs of electrically conductive pillars.

### BRIEF DESCRIPTION OF DRAWINGS

These and other features, aspects, and advantages of the present disclosure will become better understood when the following detailed description is read with reference to the accompanying drawings in which like characters represent like parts throughout the drawings.

FIG. 1A depicts a top view of a transinductor (TL) core in an exemplary embodiment.

FIG. 1B depicts an end view of the TL core of FIG. 1A in an exemplary embodiment.

FIGS. 2A-2G depict top views of various TL cores in exemplary embodiments.

FIG. 3A depicts a top view of a winding assembly that utilizes the TL core of FIGS. 1A and 1B in an exemplary embodiment.

FIG. 3B depicts an end view of the winding assembly of FIG. 3A.

FIG. 4 depicts a top view of a winding assembly that utilizes two of the TL cores of FIGS. 1A and 1B in an exemplary embodiment.

FIG. 5A depicts a top view of a winding assembly that utilizes the TL core of FIGS. 1A and 1B in another exemplary embodiment.

FIG. 5B depicts a side view of the winding assembly of FIG. 5A in an exemplary embodiment.

FIG. 5C depicts an end view of the winding assembly of FIG. 5A in an exemplary embodiment.

FIG. 6 depicts a top view of a winding assembly that utilizes the TL core of FIGS. 1A and 1B in another exemplary embodiment.

FIG. 7 depicts an end view of a power delivery module that utilizes the TL core of FIGS. 1A and 1B in an exemplary embodiment.

FIG. 8 depicts a top view of a winding assembly that utilizes two of the TL cores of FIGS. 1A and 1B in an exemplary embodiment.

FIG. 9 illustrates a partial circuit diagram corresponding to the electrical configuration of the winding assembly of FIG. 8 in an exemplary embodiment.

Unless otherwise indicated, the drawings provided herein are meant to illustrate features of embodiments of this disclosure. These features are believed to be applicable in a wide variety of systems comprising one or more embodiments of this disclosure. As such, the drawings are not meant to include all conventional features known by those of ordinary skill in the art to be required for the practice of the embodiments disclosed herein.

### DETAILED DESCRIPTION

In the following specification and the claims, reference will be made to a number of terms, which shall be defined to have the following meanings.

The singular forms “a”, “an”, and “the” include plural references unless the context clearly dictates otherwise.

“Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately”, and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The present disclosure describes transinductors (TLs) and power modules that utilize TLs. The TLs described herein enable the design of single and multiphase power modules in various embodiments. Multiphase TLs may be implemented using one or more ferrite cores that may be combined as a core assembly depending on the application. For example, two six phase TL cores may be combined in a power module in order to implement a twelve phase TL voltage regulator. TLs combine the attributes of a transformer and a coupled inductor within the same core and winding assembly, thereby optimizing power delivery in power modules. Using a custom core and winding strategy with, for example, a MgZn ferrite core, the TLs described herein utilize primary and secondary windings formed from conductive pillars that extend between two printed circuit boards (PCBs), with the TL core sandwiched therebetween. The use of conductive pillars between the two PCBs minimizes losses, optimizes efficiency, improves transient response, and addresses the spatial and thermal constraints of high-performance point of load applications, such as high-performance computing applications. The conductive pillars may also be used to conduct power and ground between the two PCBs, which also improves conduction losses between the two PCBs and minimizes the height of the power modules.

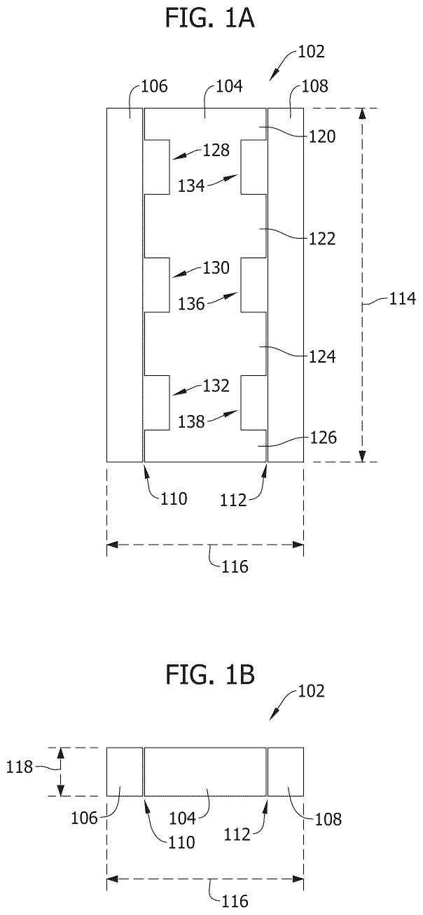

FIG. 1A depicts a top view of a TL core 102 in an exemplary embodiment. FIG. 1B depicts an end view of TL core 102 in an exemplary embodiment. In this embodiment, TL core 102 comprises a central portion 104 sandwiched between a first side portion 106 and a second side portion 108. A first gap 110 is formed between first side portion 106 and central portion 104, and a second gap 112 is formed between second side portion 108 and central portion 104. In this embodiment, TL core 102 has a length 114, a width 116, and a height 118 (See FIG. 1B). The specific relationship between length 114, width 116, and height 118 of TL core 102, and other TL cores described herein, is merely one configuration presented for purposes of discussion, and TL core 102, and other TL cores described herein, may be implemented in different configurations as desired. TL core 102 may be formed from various types of ferric material, such as MgZn.

In this embodiment, central portion 104 includes a plurality of crossbars 120, 122, 124, 126 that extend in the direction of width 116 of TL core 102. Crossbars 120, 122, 124, 126 define a plurality of slots 128, 130, 132, 134, 136, 138 that are further defined between central portion 104 and first and second side portions 106, 108 of TL core 102. In this embodiment, slots 128, 130, 132, 134, 136, 138 are sized to provide space for both primary and secondary single-turn windings (not shown), which are formed by conductive pillars that extend between two PCBs (not shown).

In some embodiments, first and second gaps 110, 112 formed between central portion 104 and first and second side portions 106, 108 have a pre-defined spacing. In some embodiments, first and second gaps 110, 112 are filled with a gap spacer (not shown), which is utilized to prevent saturation of TL core 102 and improve the stability of the inductance values desired when TL core 102 is used in a power module. The pre-defined spacings generated by first and second gaps 110, 112 also operate to linearize the BH curve of TL core 102 by reducing the permeability of TL core 102. In some embodiments, the pre-defined spacing of first and second gaps 110, 112 are the same gap. In other embodiments, first and second gaps 110, 112 utilize different pre-defined spacings. In some embodiments, the pre-defined spacing(s) of first and second gaps 110, 112 are consistent along length 114 of TL core 102. In other embodiments, the pre-defined spacing(s) of first and second gaps 110, 112 vary along length 114 of TL core 102.

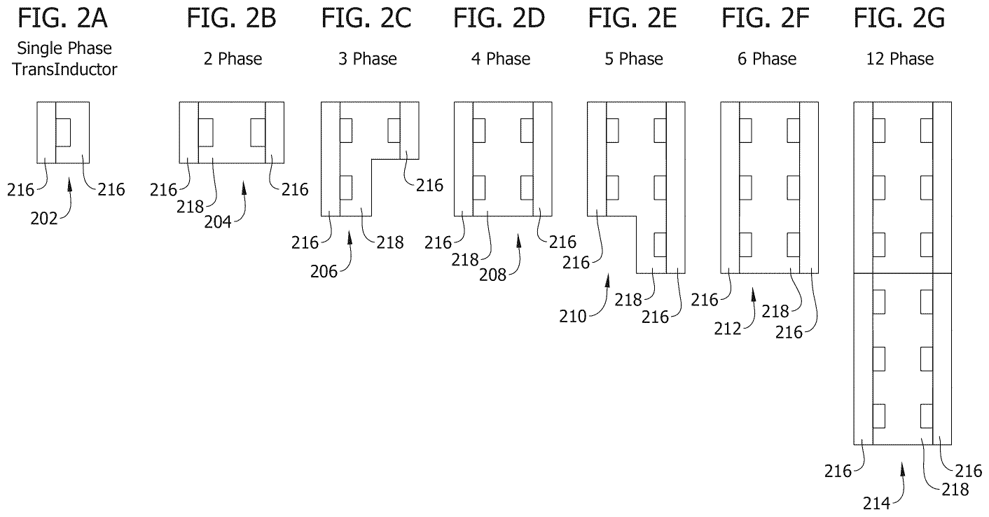

FIGS. 2A-2G depict top views of various TL cores 202, 204, 206, 208, 210, 212, 214 that may be utilized for scaling TL based power modules in exemplary embodiments. TL cores 202, 204, 206, 208, 210, 212, 214 may be formed from various types of ferric materials, such as MgZn. Further, TL cores 202, 204, 206, 208, 210, 212, 214 may include similar components and structures previously describe for TL core 102, such as side portions 216 and central portions 218, which are used to implement single turn primary and secondary windings using interconnect pillars (not shown). In this embodiment, TL core 202 does not include central portion 218, and TL core 214 is formed from two adjacent sections of TL core 212. TL core 212 may be substantially similar to TL core 102 depicted in FIG. 1.

In this embodiment, TL cores 202, 204, 206, 208, 210, 212, 214 are structured for implementing a single phase, two phase, three phase, four phase, five phase, six phase, and twelve phase power modules, respectively.

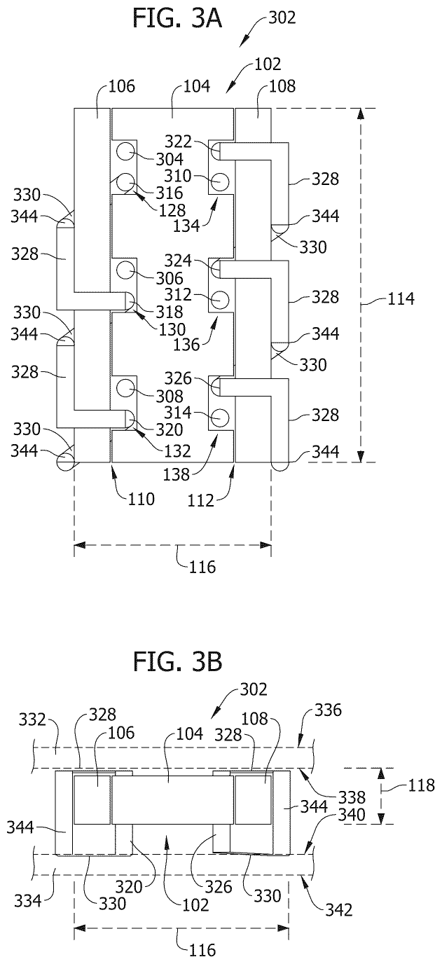

FIG. 3A depicts a top view of a winding assembly 302 that utilizes TL core 102 in an exemplary embodiment. FIG. 3B depicts an end view of winding assembly 302. In this embodiment, winding assembly 302 comprises six primary winding pillars 304, 306, 308, 310, 312, 314 disposed in slots 128, 130, 132, 134, 136, 138, respectively, which form primary windings for winding assembly 302, and six secondary winding pillars 316, 318, 320, 322, 324, 326 also disposed in slots 128, 130, 132, 134, 136, 138, respectively, which form secondary windings for winding assembly 302.

In FIG. 3A, secondary winding pillars 316, 318, 320, 322, 324, 326 are at least partially wired in series using first and second PCB traces 328, 330 formed in a first PCB 332 and a second PCB 334, respectively. Referring to FIG. 3B, first PCB 332 includes a first surface 336 and an opposing second surface 338, and second PCB 334 includes a third surface 340 and an opposing fourth surface 342. First PCB traces 328 are formed in second surface 338 of first PCB 332, and second PCB traces 330 are formed in third surface 340 of second PCB 334. In this embodiment, TL core 102 is disposed between first and second PCBs 332, 334, and primary winding pillars 304, 306, 308, 310, 312, 314 and secondary winding pillars 316, 318, 320, 322, 324, 326 extend between first and second PCBs 332, 334. FIGS. 3A and 3B also illustrate interconnect pillars 344 disposed externally to TL core 102, which are used for interconnecting first and second PCB traces 328, 330, and/or for electrically coupling first and second PCBs 332, 334 together. For example, interconnect pillars 344 may be used to couple power and ground circuits in first and second PCBs 332, 334 together. Primary winding pillars 304, 306, 308, 310, 312, 314, secondary winding pillars 316, 318, 320, 322, 324, 326, and interconnect pillars 344 are electrically conductive structures that are electrically coupled to first and second PCBs 332, 334. For example, the pillars described herein may be soldered or otherwise electrically connected to first and second PCBs 332, 334. The pillars may, for example, be soldered into blind holes formed in first and second PCBs 332, 334, and other PCBs described herein. The blind holes may extend, for example, though one or more copper layers of first and second PCBs 332, 334, and other PCBs described herein. In some embodiments, the pillars described herein extend entirely through first and second PCBs 332, 334, and other PCBs described herein.

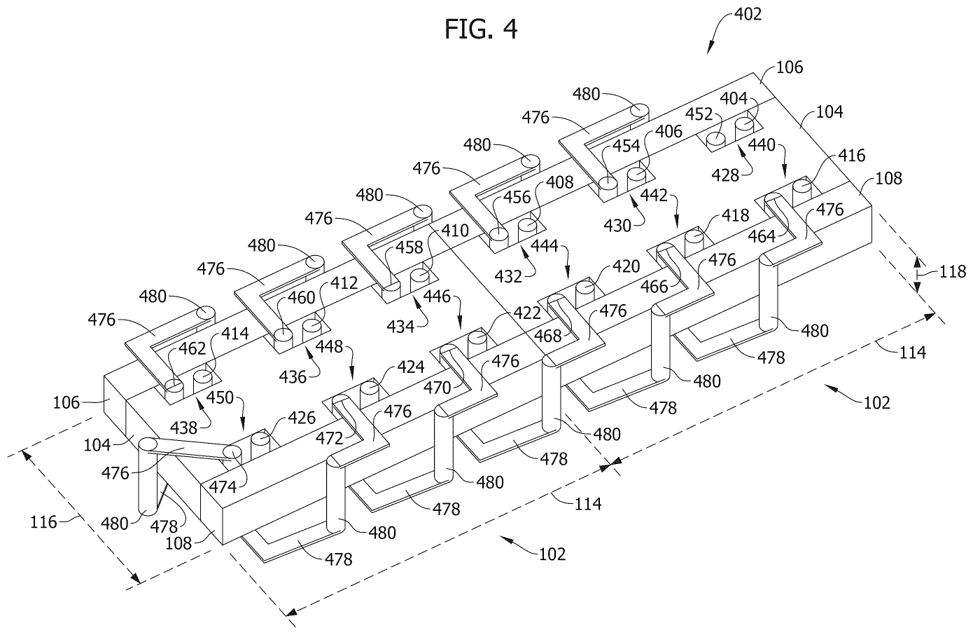

FIG. 4 depicts a top view of a winding assembly 402 that utilizes two TL cores 102 in an exemplary embodiment. In this embodiment, winding assembly 402 comprises twelve primary winding pillars 404, 406, 408, 410, 412, 414, 416, 418, 420, 422, 424, 426 disposed in slots 428, 430, 432, 434, 436, 438, 440, 442, 444, 446, 448, 450, respectively, which form primary windings for winding assembly 402. Winding assembly 402 further comprises twelve secondary winding pillars 452, 454, 456, 458, 460, 462, 464, 466, 468, 470, 472, 474 disposed in slots 428, 430, 432, 434, 436, 438, 440, 442, 444, 446, 448, 450, respectively, which form secondary windings for winding assembly 402.

In FIG. 4, secondary winding pillars 452, 454, 456, 458, 460, 462, 464, 466, 468, 470, 472, 474 are wired in series using first and second PCB traces 476, 478 formed in a first PCB (not shown) and a second PCB (not shown), respectively. In this embodiment, TL cores 102 are disposed between the first and second PCBs (not shown), and primary winding pillars 404, 406, 408, 410, 412, 414, 416, 418, 420, 422, 424, 426 and secondary winding pillars 452, 454, 456, 458, 460, 462, 464, 466, 468, 470, 472, 474 extend between first and second PCBs (not shown). FIG. 4 also illustrates interconnect pillars 480 disposed externally to TL cores 102, which are used for interconnecting first and second PCB traces 476, 478, and/or for electrically coupling the first and second PCBs (not shown) together. For example, interconnect pillars 480 may be used to couple power and ground circuits in the first and second PCBs (not shown) together. The structure of FIG. 4 is therefore similar to the structures described for FIGS. 3A and 3B.

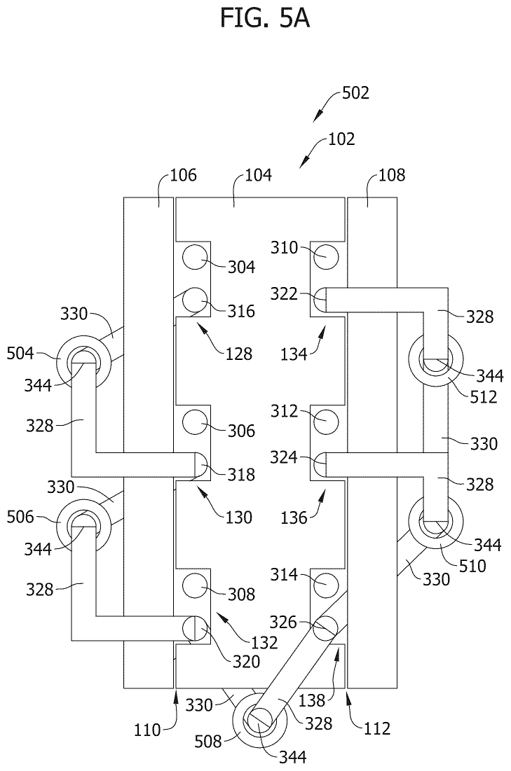

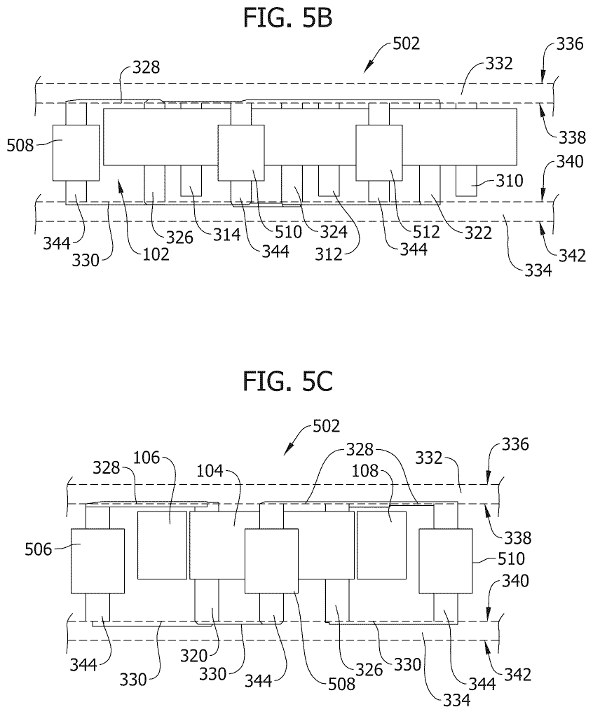

FIG. 5A depicts a top view of a winding assembly 502 that utilizes TL core 102 in another exemplary embodiment. FIGS. 5B and 5C depict a side view and an end view of winding assembly 502, respectively. Winding assembly 502 is similar to winding assembly 302 (see FIGS. 3A and 3B) with the exception that winding assembly 502 includes toroidal cores 504, 506, 508, 510, 512 wrapped around interconnect pillars 344 in order to increase the inductance of the secondary winding formed by the series connection of secondary winding pillars 316, 318, 320, 322, 324, 326, first PCB traces 328 and second PCB traces 330.

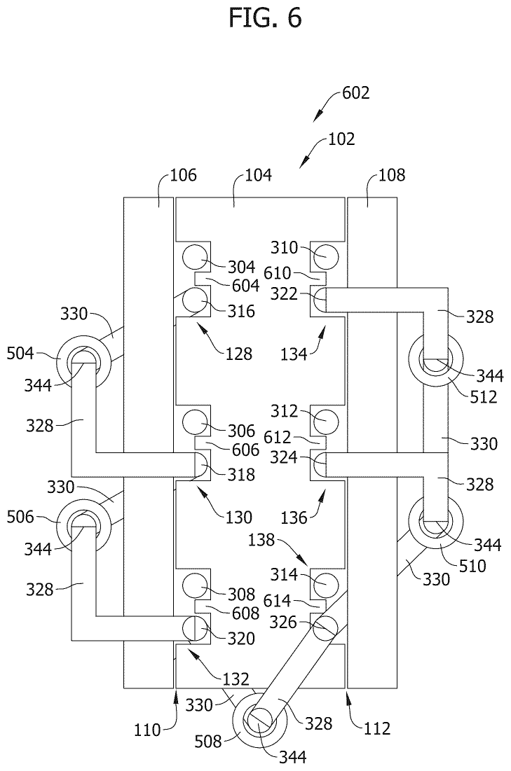

FIG. 6 depicts a top view of a winding assembly 602 that utilizes TL core 102 in another exemplary embodiment. Winding assembly 602 is similar to winding assembly 502 (see FIGS. 5A, 5B, and 5C) with the exception that central portion 104 includes tabs 604, 606, 608, 610, 612, 614 that extend into slots 128, 130, 132, 134, 136, 138, respectively, towards first and second side portions 106, 108 of TL core 102. Tabs 604, 606, 608, 610, 612, 614 may be sized as required to vary the leakage inductance between the primary and secondary windings of winding assembly 602 formed by primary winding pillars 304, 306, 308, 310, 312, 314 and secondary winding pillars 316, 318, 320, 322, 324, 326. Adjusting the leakage inductance ensures high bandwidth, minimizes latency, and improves the transient response for power modules that utilize winding assembly 602.

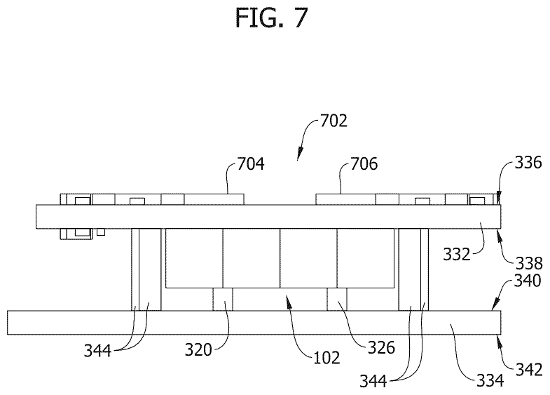

FIG. 7 depicts an end view of a power delivery module 702 that utilizes TL core 102 in an exemplary embodiment. The view in FIG. 7 is similar to the view in winding assembly 302 depicted in FIG. 3B. Power delivery module 702 includes various electrical components used to implement a voltage regulator including a plurality of power integrated circuits 704, 706. In this embodiment, power integrated circuits 704, 706 form switching nodes and are located on first surface 336 of first PCB 332. Power integrated circuits 704, 706 may be located directly over primary winding pillars 304, 306, 308, 310, 312, 314 in order to minimize parasitic losses and reduce direct current (DC) and alternating current (AC) losses, thereby improving the performance of power delivery module 702. For example, power integrated circuits 704, 706 may include switching circuits that electrically couple with primary winding pillars 304, 306, 308, 310, 312, 314, along with the associated regulation circuitry in order to implement a six phase TL voltage regulator. In some embodiments, second PCB 334 includes capacitors (e.g., disposed on fourth surface 342, not shown) used as part of the output voltage node for power delivery module 702.

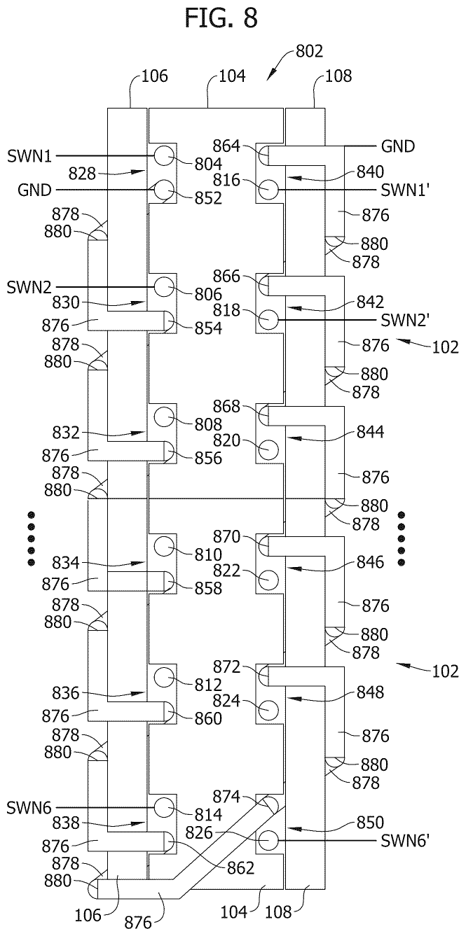

FIG. 8 depicts a top view of a winding assembly 802 that utilizes two TL cores 102 in an exemplary embodiment. In this embodiment, winding assembly 802 comprises twelve primary winding pillars 804, 806, 808, 810, 812, 814, 816, 818, 820, 822, 824, 826 disposed in slots 828, 830, 832, 834, 836, 838, 840, 842, 844, 846, 848, 850, respectively, which form primary windings for winding assembly 802. Winding assembly 802 further comprises twelve secondary winding pillars 852, 854, 856, 858, 860, 862, 864, 866, 868, 870, 872, 874 disposed in slots 828, 830, 832, 834, 836, 838, 840, 842, 844, 846, 848, 850, respectively, which form secondary windings for winding assembly 802.

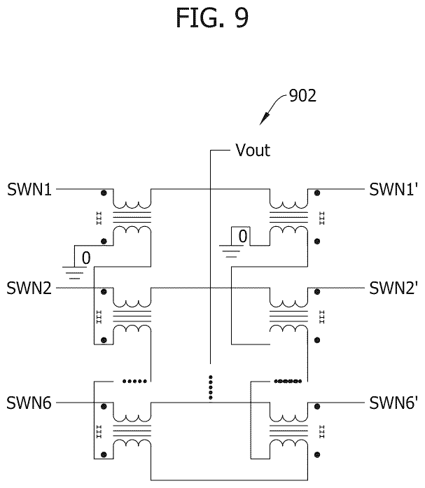

In FIG. 8, secondary winding pillars 852, 854, 856, 858, 860, 862, 864, 866, 868, 870, 872, 874 are wired in series using first and second PCB traces 876, 878 formed in a first PCB (not shown) and a second PCB (not shown), respectively. In this embodiment, TL cores 102 are disposed between the first and second PCBs (not shown), and primary winding pillars 804, 806, 808, 810, 812, 814, 816, 818, 820, 822, 824, 826 and secondary winding pillars 852, 854, 856, 858, 860, 862, 864, 866, 868, 870, 872, 874 extend between the first and second PCBs (not shown). FIG. 8 also illustrates interconnect pillars 880 disposed externally to TL cores 102, which are used for interconnecting first and second PCB traces 876, 878, and/or for electrically coupling the first and second PCBs (not shown) together. For example, interconnect pillars 880 may be used to couple power and ground circuits in the first and second PCBs (not shown) together. The structure of FIG. 8 is therefore similar to the structures described for FIGS. 3A and 3B. FIG. 8 also illustrates various switching nodes SWN1, SWN1′, SWN2, SWN2′, SWN6, SWN6′, and GND, which will be discussed with respect to FIG. 9.

FIG. 9 illustrates a partial circuit diagram 902 corresponding to the electrical configuration of winding assembly 802 of FIG. 8 in an exemplary embodiment. In circuit diagram 902, SWN1, SWN1′, SWN2, SWN2′, SWN6, SWN6′ correspond to primary winding pillars 804, 816, 806, 818, 814, 826, and secondary winding pillars 852, 864, 854, 866, 862, 874 are wired in series and grounded at both ends (e.g., grounded at secondary winding pillars 852, 864). In this embodiment, circuit diagram 902 implements a multi-phase buck-mode regulation circuit with output voltage regulated at Vout. Circuit diagram 902 may be expanded to include SWN3 and SWN3′, formed by primary winding pillars 808, 820, respectively, and secondary winding pillars 856, 868, respectively; SWN4 and SWN4′, formed by primary winding pillars 810, 822, respectively, and secondary winding pillars 858, 870, respectively; and SWN5 and SWN5′, formed by primary winding pillars 812, 824, respectively, and secondary winding pillars 860, 872, respectively. During operation, SWN1, SWN1′, SWN2, SWN2′, SWN3, SWN3′ SWN4, SWN4′, SWN5, SWN5′, SWN6, and SWN6′ are switched in a pattern to implement a multiphase buck regulator with a regulated output at Vout.

An example technical effect of the apparatus described herein includes one or more of: (a) the use of primary and secondary winding pillars along with interconnect pillars provide a compact power delivery solution, especially in the vertical direction; (b) the placement of switching nodes located approximately directly over the primary winding pillars reduce parasitic losses, AC switching losses, and DC losses; (c) the use of series adding or series connected configurations for the secondary windings significantly lowers the height of the winding assemblies that utilize the various TL cores, thereby improving the power density of the power modules; (d) various configurations of the TL cores may be used in combination as modular elements to upscale or downscale the power delivery solution depending on the requirements of the load; and (e) scalability begins with a minimal configuration of a single phase regulator, and can be easily multiplied to accommodate multiple phases (e.g., up to 32 phases or more) using the TL core sub-units described herein.

Although specific features of various embodiments of the disclosure may be shown in some drawings and not in others, this is for convenience only. In accordance with the principles of the disclosure, any feature of a drawing may be referenced and/or claimed in combination with any feature of any other drawing.

This written description uses examples to disclose the embodiments, including the best mode, and also to enable any person skilled in the art to practice the embodiments, including making and using any devices or systems and performing any incorporated methods. The patentable scope of the disclosure is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A power delivery module, comprising:
a first printed circuit board (PCB);
a second PCB;
a transinductor core sandwiched between the first PCB and the second PCB, wherein the transinductor core includes at least one slot exposing the first PCB to the second PCB; and
at least one electrically conductive pillar extending through the at least one slot that electrically connects the first PCB to the second PCB.

2. The power delivery module of claim 1, wherein:
the at least one slot comprises a plurality of slots, and
the at least one electrically conductive pillar comprises pairs of primary and secondary winding pillars, each of the pairs of primary and secondary winding pillars disposed in a different one of the plurality of slots.

3. The power delivery module of claim 2, further comprising:
a tab extending into one of the plurality of slots, the tab disposed between one of the pairs of primary and secondary winding pillars and configured to vary a leakage inductance between the one of the pairs of primary and secondary winding pillars.

4. The power delivery module of claim 2, further comprising:
a plurality of interconnect pillars external to the transinductor core that extend between the first PCB and the second PCB; and
a plurality of conductive traces formed at the first PCB and the second PCB that electrically connect, via the plurality of interconnect pillars, different pairs of the primary and secondary winding pillars together in a winding arrangement.

5. The power delivery module of claim 4, wherein:
the winding arrangement is a series winding arrangement.

6. The power delivery module of claim 4, further comprising:
a toroidal core wrapped around one of the plurality of interconnect pillars.

7. The power delivery module of claim 1, wherein:
the transinductor core comprises:
a first side portion;
a second side portion; and
a central portion sandwiched between the first side portion and the second side portion,
the at least one slot comprises a plurality of slots formed between the first side portion and the central portion and/or the second side portion and the central portion.

8. The power delivery module of claim 7, wherein:
the central portion includes a plurality of crossbars that extend towards the first side portion and the second side portion, the plurality of crossbars defining the plurality of slots.

9. The power delivery module of claim 8, wherein:
the central portion includes at least one tab between the plurality of crossbars that extends into one of the plurality of slots.

10. The power delivery module of claim 9, wherein:
the at least one electrically conductive pillar comprises a primary and secondary winding pillar, each disposed on a different side of the tab.

11. The power delivery module of claim 8, wherein:
a first gap is formed between the first side portion and the central portion,
a second gap is formed between the second side portion and the central portion, and
the first gap and the second gap have pre-defined spacing.

12. The power delivery module of claim 11, wherein:
the first gap and the second gap are filled with a gap spacer.

13. The power delivery module of claim 11, wherein:
the pre-defined spacing varies along a length of the transinductor core.

14. The power delivery module of claim 1, wherein:
the at least one slot comprises a plurality of slots,
the at least one electrically conductive pillar comprises a plurality of primary winding pillars, each disposed in one of the plurality of slots and forming a single-turn primary winding for the transinductor core, and
the power delivery module further comprises a controller configured to perform pulse width modulation phase sequencing of the plurality of primary winding pillars based on a configuration of the transinductor core.

15. A winding assembly, comprising:
a first printed circuit board (PCB);
a second PCB;
at least one transinductor core sandwiched between the first PCB and the second PCB, wherein each transinductor core comprises:
a first side portion;
a second side portion; and
a central portion sandwiched between the first side portion and the second side portion, the central portion including a plurality of crossbars that extend towards the first side portion and the second side portion, the plurality of crossbars defining a plurality of slots; and
pairs of electrically conductive pillar extending through the plurality of slots that electrically connect the first PCB to the second PCB, each of the pairs of electrically conductive pillars forming primary and secondary windings for the at least one transinductor core.

16. The winding assembly of claim 15, further comprising:
a tab extending into one of the plurality of slots, the tab disposed between one of the pairs of electrically conductive pillars and configured to vary a leakage inductance between one of the primary and secondary windings.

17. The winding assembly of claim 15, further comprising:
a plurality of interconnect pillars external to the at least one transinductor core that extend between the first PCB and the second PCB; and
a plurality of conductive traces formed at the first PCB and the second PCB that electrically connect, via the plurality of interconnect pillars, the primary and secondary windings in a winding arrangement.

18. The winding assembly of claim 17 wherein:
the winding arrangement is a series winding arrangement.

19. The winding assembly of claim 17, further comprising:
a plurality of toroidal cores, each wrapped around one of the plurality of interconnect pillars.

20. A power delivery module, comprising:
a first printed circuit board (PCB);
a second PCB;
a transinductor core sandwiched between the first PCB and the second PCB, the transinductor core comprising:
a first side portion;
a second side portion; and
a central portion sandwiched between the first side portion and the second side portion, the central portion including a plurality of crossbars that extend towards the first side portion and the second side portion, the plurality of crossbars defining a plurality of slots;
pairs of electrically conductive pillar extending through the plurality of slots that electrically connect the first PCB to the second PCB, each of the pairs of electrically conductive pillars forming a primary and secondary winding for the transinductor core;
a plurality of interconnect pillars external to the transinductor core that extend between the first PCB and the second PCB;
a plurality of conductive traces formed at the first PCB and the second PCB that electrically connect, via the plurality of interconnect pillars, the pairs of electrically conductive pillars in a winding arrangement; and
a controller configured to perform pulse width modulation (PWM) phase sequencing of the primary winding associated with each of the pairs of electrically conductive pillars.
